(19) United States
(12) Patent Application Publication
(10) Pub. No.: US 2025/0210523 A1
(43) Pub. Date: Jun. 26, 2025

(54) SEMICONDUCTOR DEVICE

(71) Applicant: Samsung Electronics Co., Ltd., Suwon-si (KR)

(72) Inventors: Jongsoon Park, Suwon-si (KR); Hyonwook Ra, Suwon-si (KR); Sangduk Park, Suwon-si (KR); Keunhee Bai, Suwon-si (KR); Sughyun SUNG, Suwon-si (KR); Jinwook Lee, Suwon-si (KR)

(21) Appl. No.: 18/757,821

(22) Filed: Jun. 28, 2024

(30) Foreign Application Priority Data
Dec. 20, 2023 (KR) 10-2023-0186494

(51) Int. Cl. H01L 23/528; H01L 21/768; H01L 23/522; H01L 27/088

(52) U.S. Cl. CPC H01L 23/5286; H01L 23/5226; H10D 84/83; H01L 21/76816

(57) ABSTRACT

A semiconductor device includes standard cells on a substrate, first interconnection lines extending in a first direction and connected to an active region and a gate structure, second interconnection lines extending in a second direction, the second interconnection lines including a first line and a second line electrically connected to the first interconnection lines, first vias electrically connecting at least one of the first interconnection lines and at least one of the second interconnection lines to each other, and a connection structure disposed on the second interconnection lines and connecting the first line and the second line to each other. The connection structure includes a first inclined via connected to the first line and inclined toward the second line, and a second inclined via connected to the second line and inclined toward the first line. Upper ends of the first and second inclined vias are connected to each other.

### CROSS-REFERENCE TO RELATED APPLICATION(S)

This application is based on and claims the benefit of priority under 35 U.S.C. § 119 to Korean Patent Application No. 10-2023-0186494 filed on Dec. 20, 2023 in the Korean Intellectual Property Office, the disclosure of which is incorporated herein by reference in its entirety.

### BACKGROUND

Aspects of the present inventive concept relate to a semiconductor device.

In the process of integrating semiconductor devices, a large number of interconnection lines have been connected to each other to facilitate signal transmission. In the process of forming and connecting, to each other, interconnection lines, defects may occur and process costs may increase.

### SUMMARY

An aspect of the present inventive concept provides a semiconductor device having a shortened signal transmission path.

According to an aspect of the present inventive concept, there is provided a semiconductor device including standard cells on a substrate, the standard cells respectively including an active region, a gate structure disposed to intersect the active region, and source/drain regions disposed on the active region, on both sides of the gate structure, first interconnection lines extending on the standard cells in a first direction, the first interconnection lines electrically connected to the active region and the gate structure, second interconnection lines extending on the first interconnection lines in a second direction, intersecting the first direction, the second interconnection lines including a first line and a second line electrically connected to the first interconnection lines, first vias electrically connecting at least one of the first interconnection lines and at least one of the second interconnection lines to each other, and a connection structure disposed on the second interconnection lines, the connection structure connecting the first line and the second line to each other. The connection structure may include a first inclined via connected to the first line, the first inclined via inclined toward the second line, and a second inclined via connected to the second line, the second inclined via inclined toward the first line. Upper ends of the first and second inclined vias may be connected to each other.

According to another aspect of the present inventive concept, there is provided a semiconductor device including standard cells on a substrate, the standard cells respectively including an active region, a gate structure disposed to intersect the active region, and source/drain regions disposed on the active region, on both sides of the gate structure, interconnection lines extending on the substrate in a first direction and a second direction, intersecting the first direction, vias extending in a third direction, perpendicular to an upper surface of the substrate, the vias electrically connecting interconnection lines disposed on different levels along the third direction, among the interconnection lines, to each other, and a first connection structure connected to respective interconnection lines positioned on the same level, among the interconnection lines, the first connection structure having contact portions having an oblique angle with respect to upper surfaces of the interconnection lines. The interconnection lines, positioned on the same level, may extend in the same direction.

According to another aspect of the present inventive concept, there is provided a semiconductor device including standard cells on a substrate, the standard cells respectively including an active region, a gate structure disposed to intersect the active region, and source/drain regions disposed on the active region, on both sides of the gate structure, a contact structure including source/drain contacts and a gate contact respectively connected to the source/drain regions and the gate structure, interconnection lines electrically connected to each of the source/drain contacts and the gate contact, and a connection structure connecting different source/drain contacts, among the source/drain contacts, to each other, the connection structure having a plurality of contact portions inclined in a direction, perpendicular to an upper surface of the substrate, and a connection portion in contact with a lower surface of at least one of the first interconnection lines.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a perspective view illustrating a semiconductor device according to an example embodiment of the present inventive concept;

FIG. 1B is a layout diagram illustrating the semiconductor device of FIG. 1A;

FIG. 1C is a cross-sectional view taken along line I-I′ of FIG. 1B;

FIG. 1D is a cross-sectional view taken along line II-II′ of FIG. 1B;

FIG. 2A is a perspective view illustrating a semiconductor device according to an example embodiment of the present inventive concept;

FIG. 2B is a layout diagram illustrating the semiconductor device of FIG. 2A;

FIG. 3A is a perspective view illustrating a semiconductor device according to an example embodiment of the present inventive concept;

FIG. 3B is a layout diagram illustrating the semiconductor device of FIG. 3A;

FIG. 3C is a cross-sectional view taken along line III-III′ of FIG. 3B;

FIG. 4A is a perspective view illustrating a semiconductor device according to an example embodiment of the present inventive concept;

FIG. 4B is a layout diagram illustrating the semiconductor device of FIG. 4A;

FIG. 5A is a perspective view illustrating a semiconductor device according to an example embodiment of the present inventive concept;

FIG. 5B is a layout diagram illustrating the semiconductor device of FIG. 5A; and

FIGS. 6A to 6I are schematic cross-sectional views illustrating a process of manufacturing a semiconductor device according to an example embodiment of the present inventive concept.

### DETAILED DESCRIPTION

Hereinafter, preferred example embodiments will be described in detail. Unless otherwise described, the terms such as “upper,” “upper portion,” “upper surface,” “lower,” “lower portion,” “lower surface,” and “side surface” are based on the drawings, and may vary depending on a direction in which a component is actually disposed.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

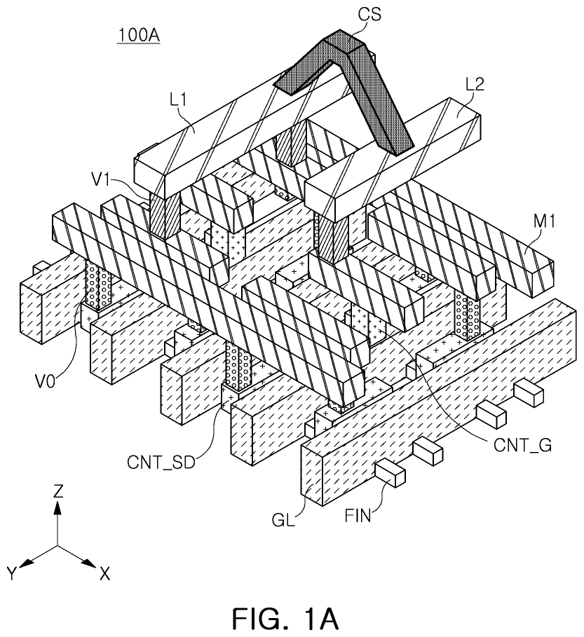

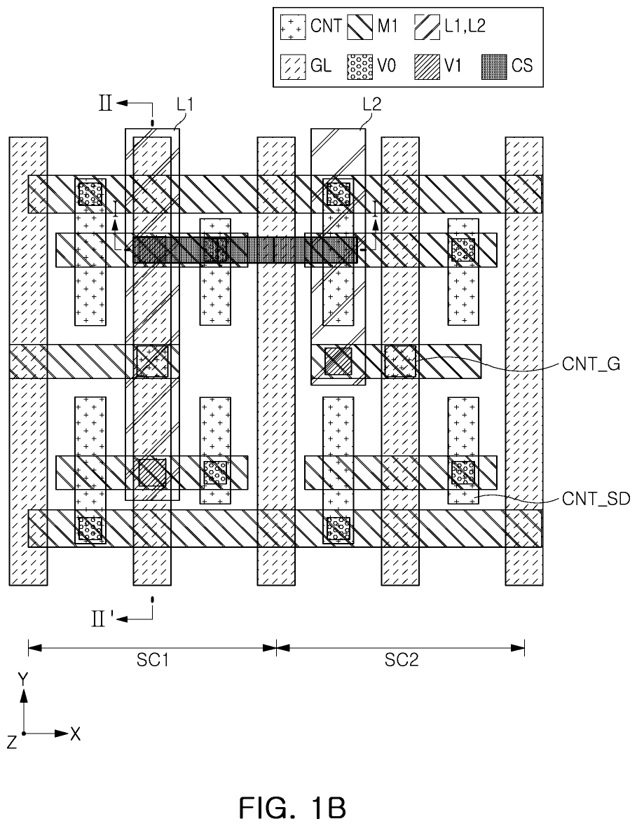

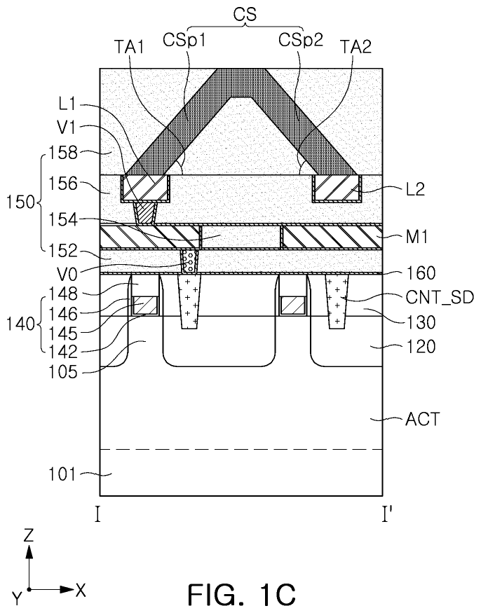

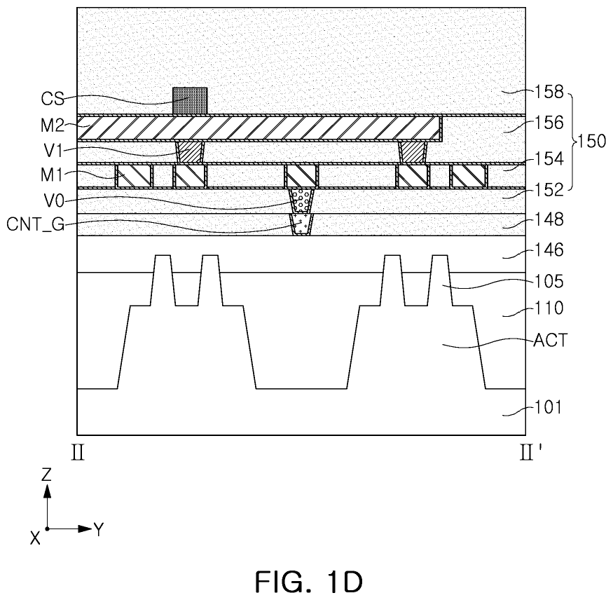

FIG. 1A is a perspective view illustrating a semiconductor device 100A according to an example embodiment of the present inventive concept, FIG. 1B is a layout diagram illustrating the semiconductor device 100A of FIG. 1A, FIG. 1C is a cross-sectional view taken along line I-I′ of FIG. 1B, and FIG. 1D is a cross-sectional view taken along line II-II′ of FIG. 1B.

Referring to FIGS. 1A and 1B, the semiconductor device 100A according to an example embodiment may include standard cells SC1 and SC2, first interconnection lines M1, second interconnection lines M2, first vias V1, and a connection structure CS. The standard cells may include various logic cells including a plurality of circuit elements, such as a transistor, a register, and the like. A logic cell may include, for example, AND, NAND, OR, NOR, exclusive OR (XOR), exclusive NOR (XNOR), an inverter (INV), an adder (ADD), a buffer (BUF), a delay (DLY), a filter (FIL), a multiplexer (MXT/MXIT), OR/AND/INVERTER (OAI), AND/OR (AO), AND/OR/INVERTER (AOI), a D flip-flop, a reset flip-flop, a master-slave flip-flop, a latch, or a combination thereof.

The semiconductor device 100A may include standard cell regions SC. A plurality of standard cells SC1 and SC2 may be disposed in the standard cell regions SC, such that circuits may be implemented. The shape and number of the plurality of standard cells SC1 and SC2, illustrated in FIGS. 1A and 1D, may be exemplary, and may be changed in various manners in example embodiments.

Referring to FIG. 1B, each of the standard cells SC1 and SC2 may include a pair of active regions ACT extending in a first direction (for example, an X-axis direction), gate lines GL extending in a second direction (for example, a Y-axis direction), contacts (i.e., contact structures) CNT connected to the active regions ACT and the gate lines GL, and lower vias V0 connected to the contacts CNT.

For example, each of the active regions ACT may include, for example, one or more active fins extending in the first direction. The active regions ACT may be disposed in different conductivity-type well regions, and may be connected to upper source/drain contacts CNT_SD. The source/drain contacts CNT_SD, connected to one of the pair of active regions ACT, may be connected to the first interconnection lines M1 through the lower via V0.

The gate lines GL may include a gate electrode, and the gate electrode may intersect the active regions ACT. The gate electrode may be shared between the pair of active regions ACT. The gate electrode may be connected to a signal transmission line, among the first interconnection lines M1, through a gate contact CNT_G.

The contacts CNT may include dummy contacts (not illustrated), and the dummy contacts may not be connected to an upper interconnection line, such as the first interconnection line M1. Depending on a component connected to the contacts CNT, the contacts CNT may include source/drain contacts CNT_SD and gate contacts CNT_G.

The first interconnection lines M1, interconnections disposed on upper portions of the active regions ACT and the gate lines GL, may extend in a first direction (for example, an X-axis direction). The first interconnection lines M1 may include a plurality of power transmission lines and signal transmission lines. The power transmission lines may be power transmission lines respectively supplying different power voltages (for example, VDD and VSS) to the semiconductor device, and may be electrically connected to source/drain regions on the active regions ACT. The signal transmission lines may be signal transmission lines supplying a signal to the semiconductor device, and may be electrically connected to the gate electrode.

The second interconnection lines M2, interconnections disposed on a level (i.e., in the Z-direction) higher than that of the first interconnection lines M1, may extend in a second direction (for example, a Y-axis direction), intersecting the first interconnection lines M1. The second interconnection lines M2 may include a first line L1 and a second line L2, electrically connected to the first interconnection lines M1. The shape and number of the second interconnection lines M2 may be exemplary, and may be changed in various manners in example embodiments. As used herein, the term “level” when used with respect to a positional relationship of an element, refers to a position along the Z-direction.

The first vias V1 may be connected to at least a portion of signal transmission lines, among the first interconnection lines M1. The first vias V1 may also be connected to other first interconnection lines M1 including a first power transmission line and a second power transmission line. The first vias V1 may extend in a direction (for example, a Z-axis direction), perpendicular to the first direction and the second direction.

The connection structure CS may be disposed on a level higher than that of the second interconnection lines M2, and may electrically connect the first line L1 and the second line L2. The connection structure CS may extend, on a plane, in the first direction (for example, the X-axis direction), but aspects of the present inventive concept are not limited thereto. A detailed description of the connecting structure CS will be described below with reference to FIG. 1C.

FIGS. 1C and 1D are cross-sectional views illustrating a semiconductor device according to example embodiments. FIGS. 1C and 1D illustrate cross-sections of the semiconductor device 100A of FIGS. 1A and 1B taken along lines I-I′ and II-II″, respectively. For ease of description, FIGS. 1C and 1D illustrate only main components of the semiconductor device 100A.

Referring to FIGS. 1C and 1D, the semiconductor device 100A may include a substrate 101, active regions ACT including active fins 105, a device isolation layer 110, source/drain regions 120, gate structures 140 including the gate electrode, a lower interlayer insulating layer 130, source/drain contacts CNT_SD, an upper interlayer insulating layer 150, a lower via V0, first interconnection lines M1, first vias V1, second interconnection lines M2, and a connection structure CS. The semiconductor device 100A may further include etch stop layers 160 (i.e., barrier layers) disposed on a lower surface of the upper interlayer insulating layer 150. The semiconductor device 100A may include FinFET devices in which the active regions ACT are transistors including the active fins 105 having a fin structure.

The substrate 101 may have an upper surface extending in a first direction (for example, an X-axis direction) and a second direction (for example, a Y-axis direction). The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon on insulator (SOI) layer, or a semiconductor on insulator (SeOI) layer.

The device isolation layer 110 may define active regions ACT in the substrate 101. The device isolation layer 110 may be formed using, for example, a shallow trench isolation (STI) process. As illustrated in FIG. 1D, the device isolation layer 110 may include a region extending into a lower portion of the substrate 101, between adjacent active regions ACT, but aspects of the present inventive concept are not limited thereto. In some example embodiments, the device isolation layer 110 may have a curved upper surface having a higher level as a distance to the active fins 105 gradually decreases. The device isolation layer 110 may be formed of an insulating material, and may include, for example, oxide, nitride, or a combination thereof.

The active regions ACT may be defined by the device isolation layer 110 in the substrate 101, and may be disposed to extend in the first direction (for example, the X-axis direction). The active fins 105 may protrude from the substrate 101. Upper ends of the active fins 105 may be disposed to protrude to a predetermined height from an upper surface of the device isolation layer 110. The active fins 105 may be formed as a portion of the substrate 101, or may include an epitaxial layer grown from the substrate 101. On both sides of the gate structures 140, the active fins 105 may be partially recessed, and the source/drain regions 120 may be disposed on the recessed active fins 105. In some example embodiments, the active regions ACT may have doped regions including impurities. For example, the active fins 105 may include impurities diffused from the source/drain regions 120 in a region in contact with the source/drain regions 120. In example embodiments, the active fins 105 may be omitted. In this case, the active regions ACT may have a flat upper surface.

The source/drain regions 120 may be disposed on recess regions in the active fins 105 are recessed, on both sides of the gate structures 140. The source/drain regions 120 may be provided as source regions or drain regions of the transistors. Upper surfaces of the source/drain regions 120 may be positioned on a height level the same as or similar to that of lower surfaces of the gate structures 140 in a cross-section of the semiconductor device 100A in the first direction (for example, the X-axis direction). However, relative heights of the source/drain regions 120 and the gate structures 140 may be changed in various manners in some example embodiments. The source/drain regions 120 may have angled side surfaces in a cross-section of the semiconductor device 100A in the second direction (for example, the Y-axis direction). However, in example embodiments, the source/drain regions 120 may have various shapes, for example, one shape, among polygonal, circular, oval, and rectangular shapes.

The source/drain regions 120 may be formed of an epitaxial layer, and may include, for example, silicon (Si), silicon germanium (SiGe), or silicon carbide (SiC). In addition, the source/drain regions 120 may further include impurities such as arsenic (As) and/or phosphorus (P). In example embodiments, the source/drain regions 120 may include a plurality of regions including an element and/or a doping element having different concentrations.

The gate structures 140 may be disposed on upper portions of the active regions ACT to intersect the active regions ACT and extend in a direction, for example, the Y-direction. The gate structures 140 may be disposed to correspond to the gate electrodes of FIG. 1B. Channel regions of the transistors may be formed in the active fins 105, intersecting the gate structures 140. The gate structure 140 may include a gate insulating layer 142, a gate electrode layer 145, gate spacer layers 146, and a gate capping layer 148.

The gate insulating layer 142 may be disposed between the active fin 105 and the gate electrode layer 165. In example embodiments, the gate insulating layer 142 may include a plurality of layers, or may be disposed to extend onto a side surface of the gate electrode layer 145. The gate insulating layer 142 may include oxide, nitride, or a high-K material. The high-K material may refer to a dielectric material having a dielectric constant higher than that of a silicon oxide film (SiO₂).

The gate electrode layer 145 may include a conductive material, for example, a metal nitride such as titanium nitride (TiN), tantalum nitride (TaN), or tungsten nitride (WN), and/or a metal material such as aluminum (Al), tungsten (W), or molybdenum (Mo) or a semiconductor material such as doped polysilicon. The gate electrode layer 145 may include two or more multiple layers. Depending on a structure of the semiconductor device 100A, the gate electrode layers 145 may be disposed to be isolated from each other in the second direction, between at least some adjacent transistors.

The gate spacer layers 146 may be disposed on both sides of the gate electrode layer 145. The gate spacer layers 146 may insulate the source/drain regions 120 and the gate electrode layer 145 from each other. The gate spacer layers 146 may have a multilayer structure in some example embodiments. The gate spacer layers 146 may be formed of oxide, nitride, and oxynitride. In particular, the gate spacer layers 146 may be formed of a low-K film. For example, the gate spacer layers 146 may include at least one of SiO, SiN, SiCN, SiOC, SiON, and SiOCN.

The gate capping layer 148 may be disposed on an upper portion of the gate electrode layer 145, and may have a lower surface and side surfaces respectively surrounded by the gate electrode layer 145 and the gate spacer layers 146. The gate capping layer 148 may be formed of, for example, oxide, nitride, and oxynitride.

The lower interlayer insulating layer 130 may be disposed to cover the source/drain regions 120 and the gate structures 140. The lower interlayer insulating layer 130 may include, for example, at least one of oxide, nitride, and oxynitride, and may include a low-K material.

The source/drain contacts CNT_SD may pass through the lower interlayer insulating layer 130 to be connected to the source/drain regions 120, and may apply an electrical signal to the source/drain regions 120. The source/drain contacts CNT_SD may be disposed to recess (i.e., extend into) the source/drain regions 120 to a predetermined depth, but aspects of the present inventive concept are not limited thereto. The source/drain contacts CNT_SD may include a conductive material, for example, a metal material such as tungsten (W), aluminum (Al), copper (Cu), or a semiconductor material such as doped polysilicon. In some example embodiments, the source/drain contacts CNT_SD may include a barrier metal layer disposed along an external surface thereof. In addition, in some example embodiments, the source/drain contacts CNT_SD may further include a metal-semiconductor layer, such as a silicide layer, disposed at an interface in contact with the source/drain regions 120.

The upper interlayer insulating layer 150 may cover the source/drain contacts CNT_SD, and may be disposed on a level the same as those of the lower vias V0, the first interconnection lines M1, the first vias V1, the second interconnection lines M2, and the connection structure CS. The upper interlayer insulating layer 150 may include first to fourth insulating layers 152, 154, 156, and 158, and may be disposed on a level the same as those of the lower vias V0, the first interconnection lines M1, the first vias V1, the second interconnection lines M2 (e.g., first line L1 and second line L2), and the connection structure CS. The upper interlayer insulating layer 150 may be formed of silicon oxide or a low-k material. The upper interlayer insulating layer 150 may include, for example, at least one of SiO, SiN, SiCN, SiOC, SiON, and SiOCN.

The etch stop layers 160 may be disposed on lower surfaces of the first to fourth insulating layers 152, 154, 156, and 158, respectively. The etch stop layers 160 may function as an etch stop layer in an etching process for forming the lower vias V0, the first interconnection lines M1, the first vias V1, and the second interconnection lines M2. For example, as illustrated in FIG. 1C, the etch stop layers 160 may be disposed between the second interconnection lines M1 and the third insulating layer 156, and between the second interconnection lines M1 and the first vias V1. The etch stop layers 160 may extend from side and lower surfaces of the second interconnection lines M1 to lower surfaces of the first vias V1 along side surfaces of the first vias V1. The etch stop layers 160 may contact the second interconnection lines M1, the third insulating layer 156, and the first vias V1. The etch stop layers 160 may include a high-K material, for example, silicon nitride or aluminum oxide.

The lower vias V0, the first interconnection lines M1, the first vias V1, the second interconnection lines M2, and the connection structure CS may be disposed to be sequentially stacked from the bottom. As illustrated in FIG. 1C, the connection structure CS may connect the first line L1 and the second line L2, among the second interconnection lines M2, to each other. As illustrated in FIG. 1C, the connection structure CS may connect the first line L1 and the second line L2 through contact with the first line L1 and the second line L2. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

The connection structure CS may include a first inclined via CSp1 connected to the first line L1, the first inclined via CSp1 inclined toward the second line L2, and a second inclined via CSp2 connected to the second line L2, the second inclined via CSp2 inclined toward the first line L1. The connection structure CS may have a structure in which upper ends of the first and second inclined vias CSp1 and CSp2 are connected to each other. The first inclined via CSp1 may be inclined at a first inclined angle TA1 with respect to an upper surface of the first line L1, and the second inclined via CSp2 may be inclined at a second inclination angle TA2 with respect to an upper surface of the second line L2. The first inclination angle TA1 and the second inclination angle TA2 may be the same, but aspects of the present inventive concept are not limited thereto. On a plane, the first and second inclination vias CSp1 and CSp2 may have the same length, but aspects of the present inventive concept are not limited thereto. The first and second inclined vias CSp1 and CSp2 may be symmetrical to each other in a direction (for example, a Z-axis direction), perpendicular to an upper surface of the substrate 101. Portions of the first and second inclined vias CSp1 and Csp2 connected to the second interconnection lines M2 may be referred to as contact portions.

Only one connection structure CS is illustrated, but the number of connection structures CS is not limited thereto. In some example embodiments, a plurality of connection structures CS positioned on the same level may be provided. In an example embodiment, the plurality of connection structures CS may be in contact with each other, and thus may have an M-shaped structure.

The connection structure CS, an integrated structure not forming interconnections disposed on a level higher than that of the second interconnection lines M2, may electrically connect the second interconnection lines M2 to each other. Thus, in the semiconductor device according to the present example embodiment, a process of forming an upper interconnection may be omitted. A path through which an electrical signal is transmitted may be shortened in the semiconductor device.

The lower vias V0, the first interconnection lines M1, the first vias V1, the second interconnection lines M2, and the connection structure CS may include a metal material, for example, at least one of aluminum (Al), copper (Cu), and tungsten (W).

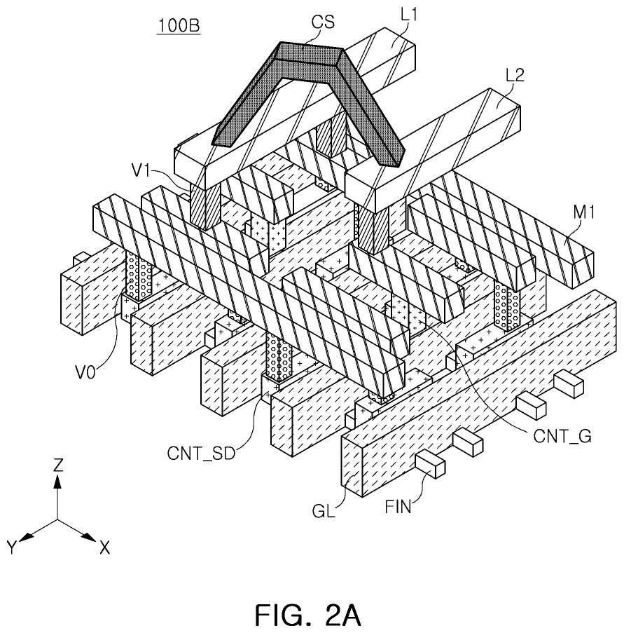

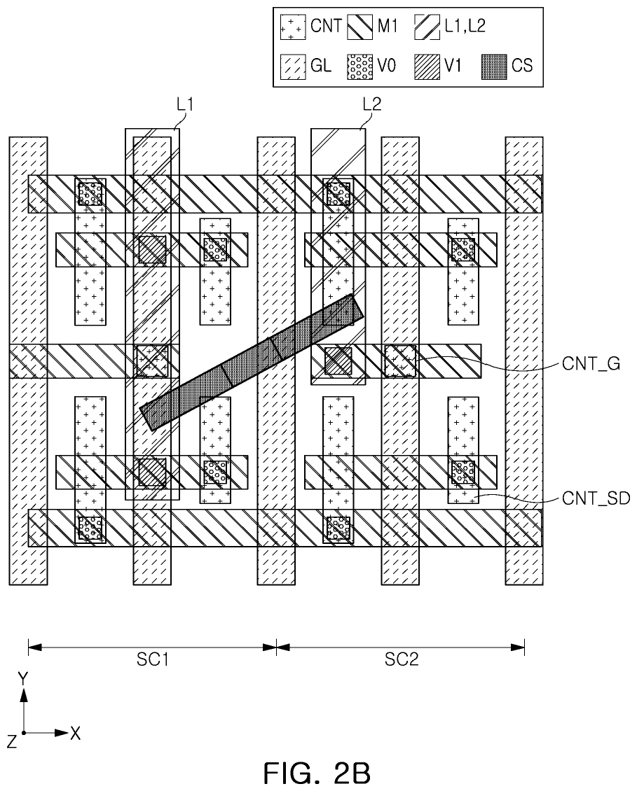

FIG. 2A is a perspective view illustrating a semiconductor device 100B according to an example embodiment of the present inventive concept, and FIG. 2B is a layout diagram illustrating the semiconductor device 100B of FIG. 2A.

Referring to FIGS. 2A and 2B, the semiconductor device 100B according to an example embodiment have features the same as or similar to those described with reference to FIGS. 1A to 1D, except that a connection structure CS does not extend on a plane to be parallel to a first direction. The connection structure CS may electrically connect a first line L1 and a second line L2 to each other. On a plane, the connection structure CS may extend in a direction oblique to each of the first direction (for example, an X-axis direction) and a second direction (for example, a Y-axis direction). Existing interconnection lines may be formed to extend to be parallel to the first direction or the second direction, intersecting the first direction, but the connection structure CS of the semiconductor device 100B according to the present example embodiment is not limited thereto. A degree of structural freedom may be increased.

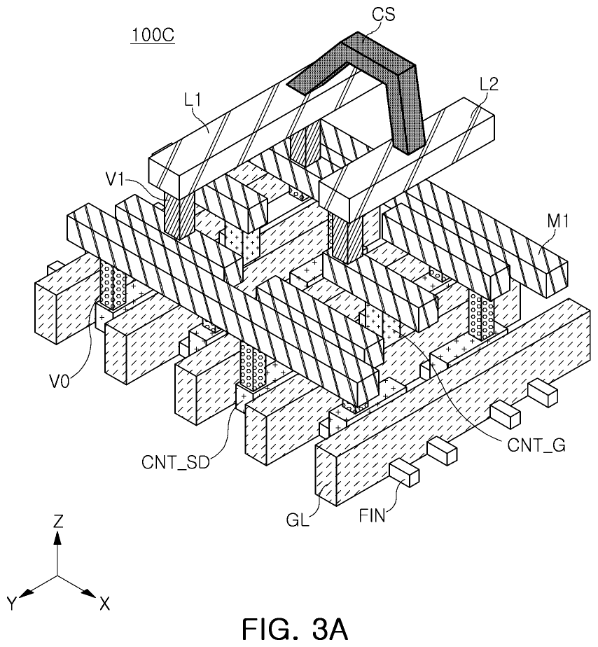

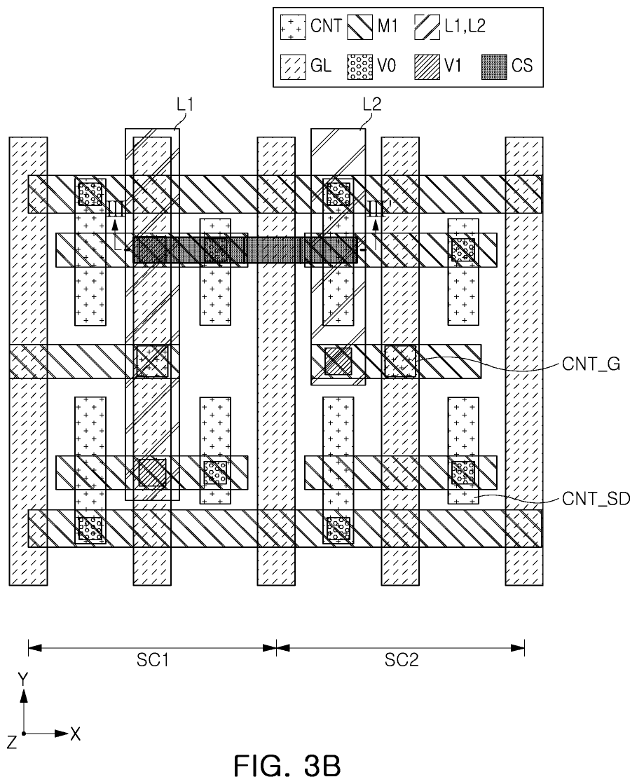

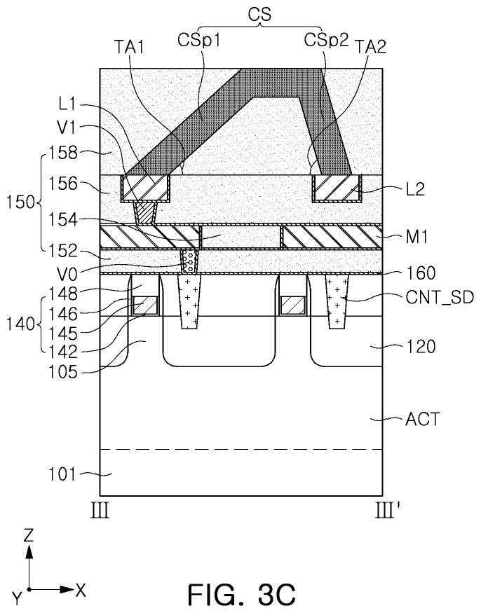

FIG. 3A is a perspective view illustrating a semiconductor device 100C according to an example embodiment of the present inventive concept, FIG. 3B is a layout diagram illustrating the semiconductor device 100C of FIG. 3A, and FIG. 3C is a cross-sectional view taken along line III-III′ of FIG. 3B.

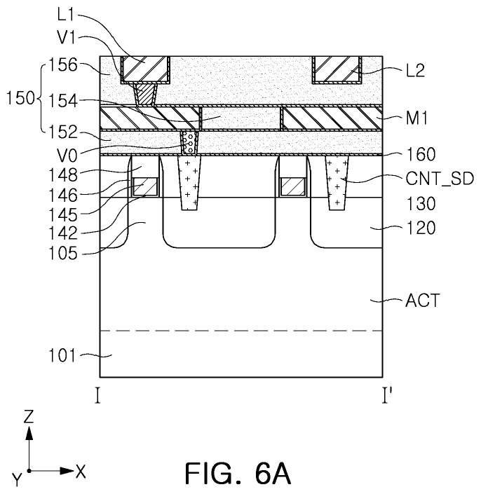

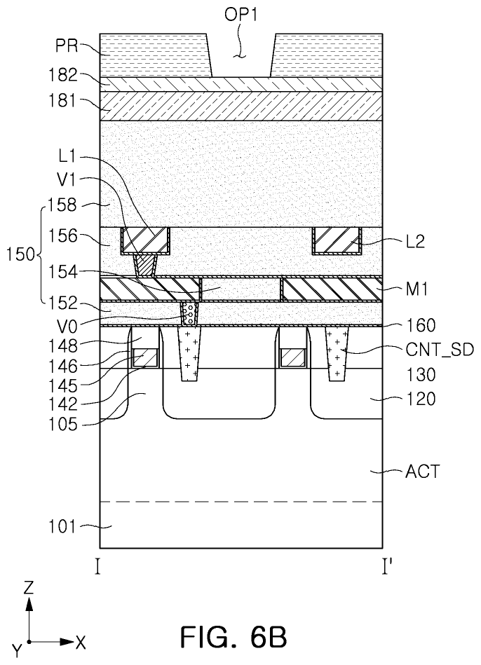

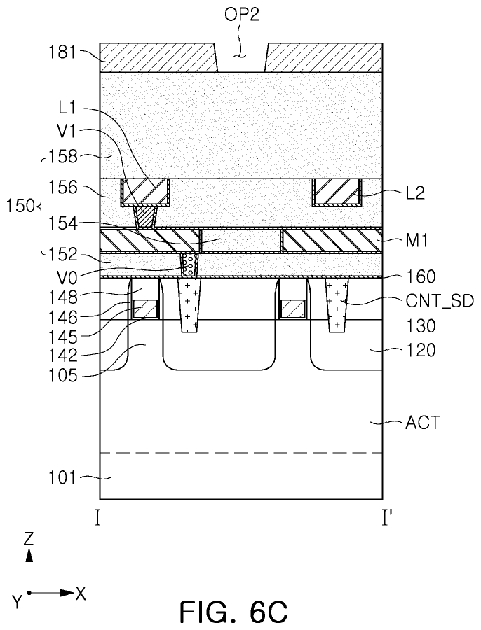

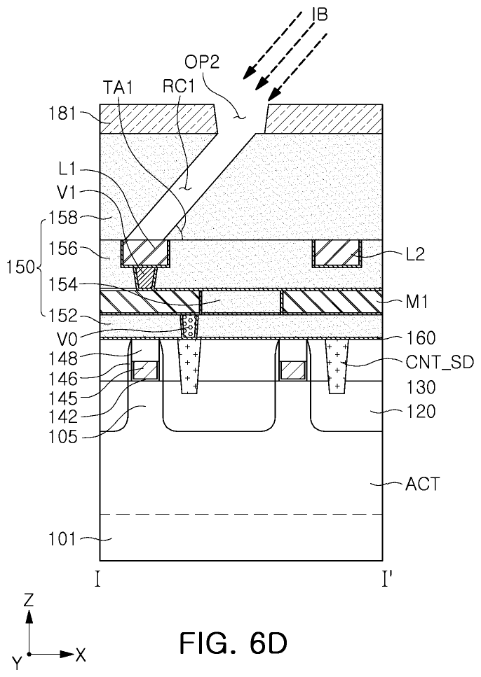

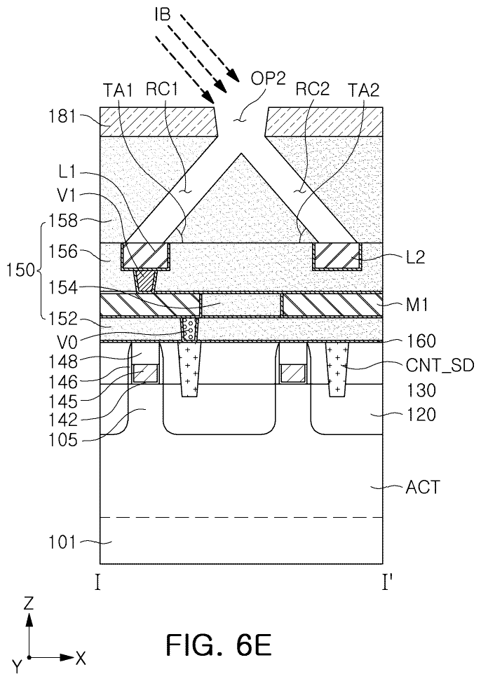

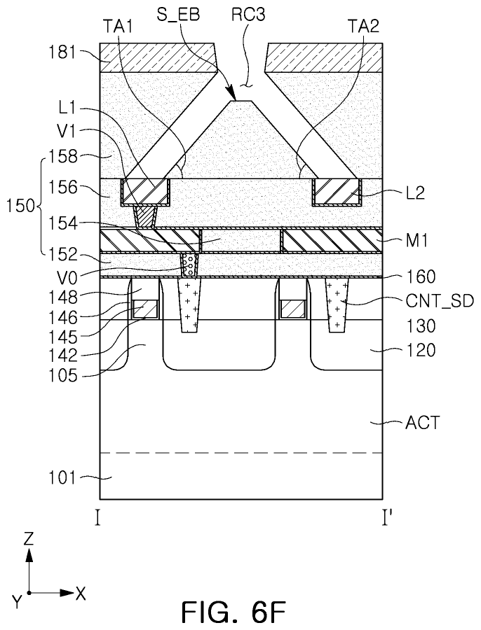

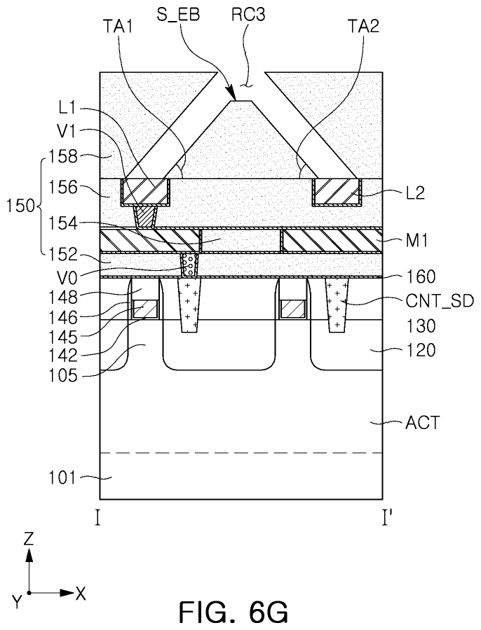

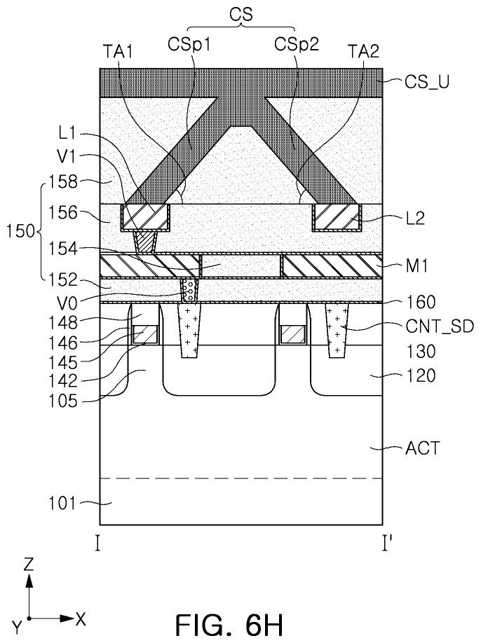

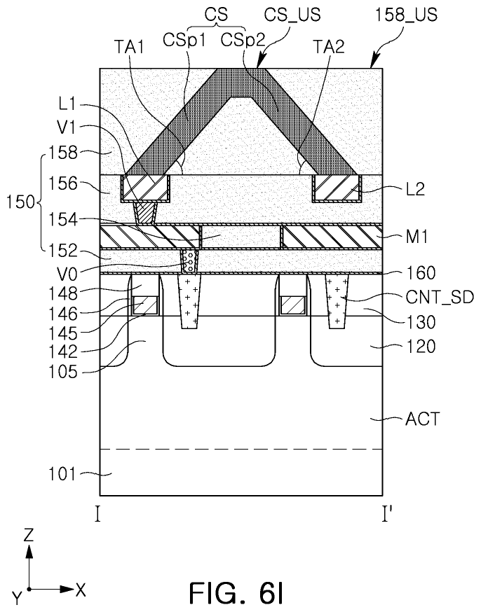

Referring to FIGS. 3A and 3C, the semiconductor device 100C according to an example embodiment may have features the same as or similar to those described with reference to FIGS. 1A to 2B, except that first and second inclined vias CSp1 and CSp2 of a connection structure CS have different lengths. The connection structure CS may electrically connect a first line L1 and a second line L2 to each other. The first inclined via CSp1 may be inclined at a first inclination angle TA1 with respect to an upper surface of the first line L1, and the second inclined via CSp2 may be inclined at a second inclination angle TA2 with respect to an upper surface of the second line L2. The first inclination angle TA1 and the second inclination angle TA2 may have different magnitudes. In the semiconductor device 100C according to the present example embodiment, the first inclination angle TA1 may be lower (i.e., less) than the second inclination angle TA2, and the first inclined via CSp1 may be longer (i.e., greater) than the second inclined via CSp2, on a plane (for example, a Z-X plane). In a process of forming a connection structure CS (see FIGS. 6D and 6E), the first inclination angle TA1 and the second inclination angle TA2 may be adjusted to respectively adjust lengths of the first inclined via CSp1 and the second inclined via CSp2. As a result, a structural freedom of the connection structure CS may be increased depending on a distance between the first line L1 and the second line L2.

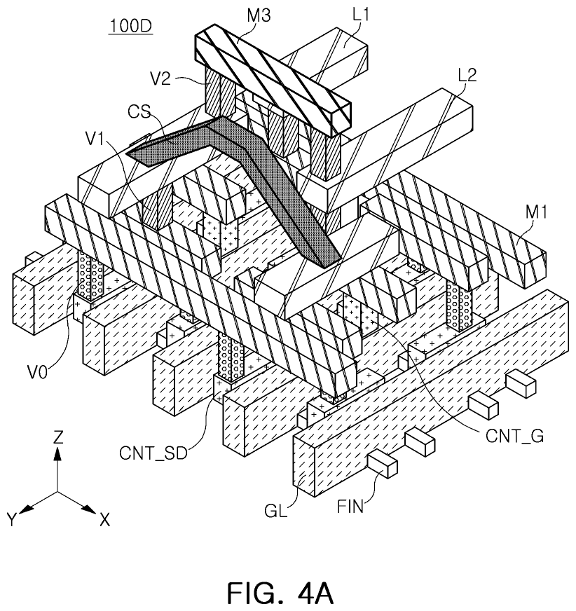

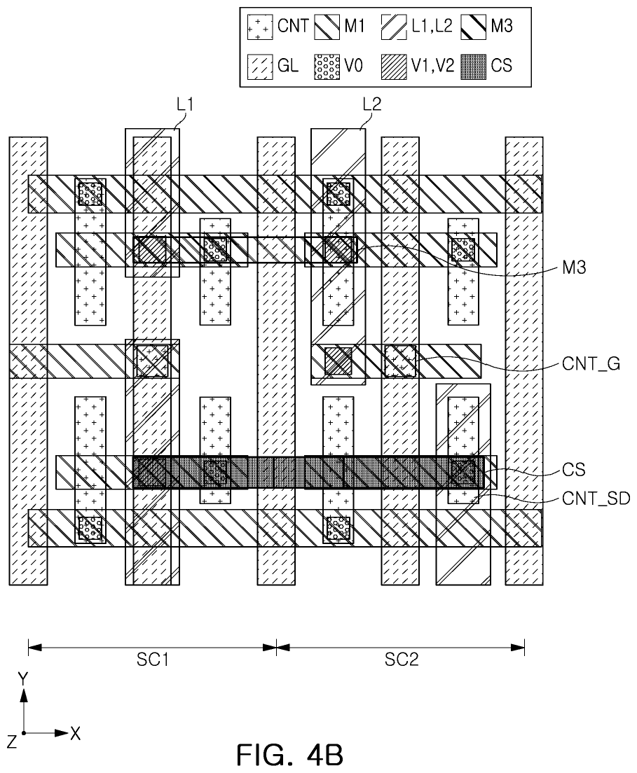

FIG. 4A is a perspective view illustrating a semiconductor device 100D according to an example embodiment of the present inventive concept, and FIG. 4B is a layout diagram illustrating the semiconductor device 100D of FIG. 4A.

Referring to FIGS. 4A and 4B, the semiconductor device 100D according to an example embodiment may have features the same as or similar to those described with reference to FIGS. 1A to 3C, except that third interconnection lines M3 and second vias V2 are further included. The semiconductor device 100D according to the present example embodiment may further include the third interconnection lines M3 disposed on a level higher than that of second interconnection lines M2, extending in a first direction (for example, an X-direction), and electrically connected to the second interconnection lines M2, and the second vias V2 electrically connecting at least one of the second interconnection lines M2 and at least one of the third interconnection lines M3 to each other. The second vias V2 may extend in a vertical direction (for example, a Z-axis direction). At least a portion of the connection structure CS may be positioned on a level the same as that of the third interconnection lines M3 or the second vias V2. A portion of the connection structure CS in which upper ends of first and second inclined vias CSp1 and CSp2 are connected to each other may be positioned on a level the same or lower than that of uppermost ends of the third interconnection lines M3. A position in which the connection structure CS is formed is not limited thereto. In an example embodiment, at least a portion of the connection structure CS may be positioned on a level the same as those of the second interconnection lines M2 and first vias V1, and the connection structure CS may connect different first interconnection lines M1 to each other on the first interconnection lines M1. Depending on an arrangement relationship between the second interconnection lines M2, the connection structure CS may be introduced or upper third interconnection lines M3 may be formed, thereby increasing a degree of structural freedom.

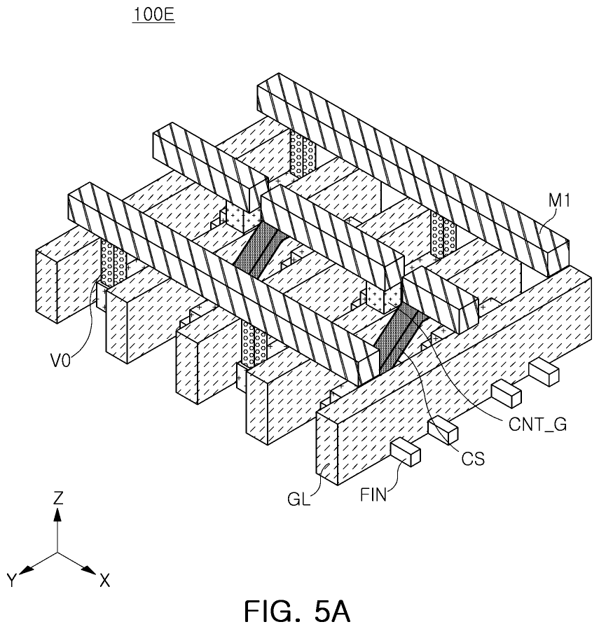

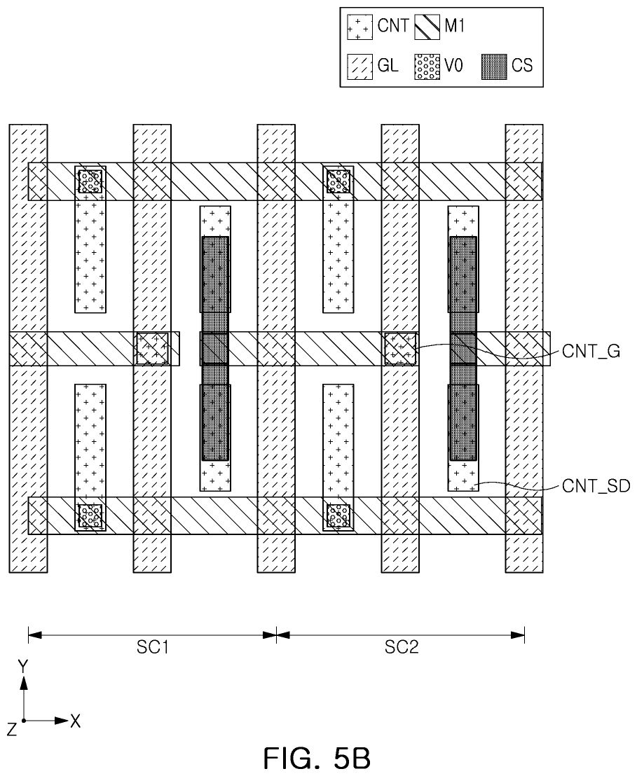

FIG. 5A is a perspective view illustrating a semiconductor device 100E according to an example embodiment of the present inventive concept, and FIG. 5B is a layout diagram illustrating the semiconductor device 100E of FIG. 5A.

Referring to FIGS. 5A and 5B, the semiconductor device 100E according to an example embodiment may have features the same as or similar to those described with reference to FIGS. 1A to 4B, except that first interconnection lines M1 may be connected to the connection structure CS. Additionally, the connection structure CS may be connected to a source/drain contact CNT_SD. For example, the connection structure CS may have a plurality of contact portions inclined in a direction, perpendicular to an upper surface of a substrate, and each of the plurality of contact portions may be connected to and in contact with the source/drain contacts CNT_SD such that different source/drain contacts CNT_SD are connected to each other. Upper ends of the plurality of contact portions may be in contact with each other, and may be connected to each other at one point. The one point may be in contact with a lower surface of one of the first interconnection lines M1. Components, not overlapping in a vertical direction (for example, a Z-axis direction), may be electrically connected to each other by introducing the connection structure CS of the semiconductor device 100E according to the present example embodiment, thereby increasing a degree of structural freedom.

FIGS. 6A to 6I are schematic cross-sectional views illustrating a process of manufacturing the connection structure CS of the semiconductor device 100A according to an example embodiment of the present inventive concept.

Referring to FIG. 6A, a semiconductor device may be prepared in which lower vias V0, first interconnection lines M1, first vias V1, and second interconnection lines M2 (i.e., the first line L1 and the second line L2) are sequentially stacked in a vertical direction (for example, a Z-axis direction). The lower vias V0 may extend in the vertical direction (for example, the Z-axis direction) between a source/drain contact CNT_SD and the first interconnection lines M1, and may electrically connect the source/drain contact CNT_SD and the first interconnection lines M1 to each other. The first vias V1 may extend in the vertical direction (for example, the Z-axis direction) between the first interconnection lines M1 and the second interconnection lines M2, and may electrically connect the first interconnection lines M1 and the second interconnection lines M2 to each other. The first interconnection lines M1 may extend in a first direction (for example, an X-axis direction), and the second interconnection lines M2 may extend in a second direction (for example, a Y-axis direction). At least a portion of each of the lower vias V0, the first interconnection lines M1, the first vias V1, and the second interconnection lines M2 may be covered by upper interlayer insulating layers 150. Upper surfaces of the second interconnection lines M2 may be exposed from (i.e., not covered by) a third insulating layer 156.

Referring to FIG. 6B, a fourth insulating layer 158, a carbon-containing film 181, a capping layer 182, and a photoresist film PR may be sequentially stacked on the third insulating layer 156 in the vertical direction. The capping layer 182 may include an insulating material such as SiON or the like. The photoresist film PR, disposed on the capping layer 182, may have a portion on which a subsequent etching process is to be performed, as a first opening OP1. The first opening OP1 may not overlap first and second lines L1 and L2 in the vertical direction (for example, the Z-axis direction).

Referring to FIG. 6C, a portion of the capping layer 182 and the carbon-containing film 181 may be removed using an etching process through the first opening OP1 to form a second opening OP2. The photoresist film PR may be formed to have a small thickness by introducing the capping layer 182 and the carbon-containing film 181, disposed on a lower portion of the photoresist film PR. In a subsequent process, the capping layer 182 and the photoresist film PR, disposed on an upper end of the carbon-containing film 181, may be removed.

Referring to FIG. 6D, an ion beam IB may be scanned at a first inclination angle TA1 with respect to an upper surface of the first line L1 to form a first recess region RC1. The ion beam IB may be scanned toward an upper surface of the fourth insulating layer 158 through the second opening OP2. The first recess region RC1 may be formed by removing a portion of the fourth insulating layer 158 using the ion beam IB. A sidewall of the first recess region RC1 may be inclined at the first inclination angle TA1 with respect to the upper surface of the first line L1. In the first recess region RC1, the upper surface of the first line L1 may be exposed from the fourth insulating layer 158.

Referring to FIG. 6E, the ion beam IB may be scanned at a second inclination angle TA2 with respect to an upper surface of the second line L2 to form a second recess region RC2. The ion beam IB may be scanned toward the upper surface of the fourth insulating layer 158 through the second opening OP2. The second recess region RC2 may be formed by removing a portion of the fourth insulating layer 158 using the ion beam IB. A sidewall of the second recess region RC2 may be inclined at the second inclination angle TA2 with respect to the upper surface of the second line L2. In the second recess region RC2, the upper surface of the second line L2 may be exposed from the fourth insulating layer 158. The first recess region RC1 and the second recess region RC2 may intersect to each other at upper portions of the first recess region RC1 and the second recess region RC2, and the intersection may partially overlap the second opening OP2 in the vertical direction. In the above-described process, the first inclination angle TA1 or the second inclination angle TA2 at which the ion beam IB is scanned may be adjusted to change a length or width of the first recess region RC1 or the second recess region RC2.

Referring to FIG. 6F, a portion of the fourth insulating layer 158 may be etch-backed to form a third recess region RC3. A portion of the fourth insulating layer 158 may be etched to form an etched surface S_EB. The etched surface S_EB may be parallel to the upper surface of the fourth insulating layer 158, but aspects of the present inventive concept are not limited thereto. The third recess region RC3 may correspond to a region in which the connection structure CS is formed in a subsequent process. As the etched surface S_EB is formed, an area of the connection structure CS in contact with the first and second inclined vias CSp1 and CSp2 may be increased, thereby improving a resistance issue.

Referring to FIG. 6G, the carbon-containing film 181, disposed on the fourth insulating layer 158, may be removed. As the carbon-containing film 181 is removed, the upper surface of the fourth insulating layer 158 may be exposed, and the third recess region RC3 may also be exposed.

Referring to FIG. 6H, the connection structure CS and an upper connection structure CS_U may be formed using a deposition process. The deposition process may include a physical vapor deposition (PVD) process and a chemical vapor deposition (CVD) process. A metal material may be deposited using the deposition process to form a connection structure CS, and the connection structure CS may include at least one of aluminum (Al), copper (Cu), and tungsten (W). The third recess region RC3 may be filled with the connection structure CS, and the upper connection structure CS_U may be disposed on the connection structure CS and the fourth insulating layer 158. The connection structure CS and the upper connection structure CS_U may be an integrated structure.

Referring to FIG. 6I, a metal chemical mechanical planarization (metal CMP) or an etching process may be performed on the upper connection structure CS_U, disposed on a level higher than that of an upper surface 158_US of the fourth insulating layer 158, to form a connection structure CS. The upper connection structure CS_U may be removed using the metal planarization process or the etching process, and the upper surface CS_US of the connection structure CS may be exposed from the fourth insulating layer 158. The upper surface CS_US of the connection structure CS may be coplanar with the upper surface 158_US of the fourth insulating layer 158. A lower surface of the connection structure CS may be connected to, and in contact with, the first line L1 and the second line L2, and an electrical signal may be transmitted between the lines. A position in which the above-described series of processes are performed is not limited to upper portions of the second interconnection lines M2. In some example embodiments, the above-described series of processes may be performed on upper portions of the first interconnection lines M1. The above-described series of processes may be processes for forming the connection structures CS in the semiconductor devices 100A, 100B, 100C, 100D, and 100E according to the above-described example embodiments. For purposes of brevity, the disclosed different connection structures CS have been described with respect to different semiconductor devices 100A, 100B, 100C, 100D, and 100E. However, a plurality of different types of the disclosed connection structures CS may be provided in the same semiconductor device. For example, the plurality of different types of the disclosed connection structures CS may be provided in the same semiconductor device along the X, Y, and Z directions.

According to example embodiments of the present inventive concept, an integrated connection structure, connecting upper interconnection lines to each other, may be introduced, thereby providing a semiconductor device having a shortened signal transmission path.

While example embodiments have been shown and described above, it will be apparent to those skilled in the art that modifications and variations could be made without departing from the scope of the present inventive concept as defined by the appended claims.

What is claimed is:

1. A semiconductor device comprising:
standard cells on a substrate, the standard cells respectively including an active region, a gate structure disposed to intersect the active region, and source/drain regions disposed on the active region, on both sides of the gate structure;
first interconnection lines extending on the standard cells in a first direction, the first interconnection lines electrically connected to the active region and the gate structure;
second interconnection lines extending on the first interconnection lines in a second direction, intersecting the first direction, the second interconnection lines including a first line and a second line electrically connected to the first interconnection lines;
first vias electrically connecting at least one of the first interconnection lines and at least one of the second interconnection lines to each other; and
a connection structure on the second interconnection lines, the connection structure connecting the first line and the second line to each other,
wherein the connection structure includes a first inclined via connected to the first line, the first inclined via inclined toward the second line, and a second inclined via connected to the second line, the second inclined via inclined toward the first line, and
upper ends of the first and second inclined vias are connected to each other.

2. The semiconductor device of claim 1, further comprising:
third interconnection lines disposed on the second interconnection lines in the first direction, the third interconnection lines electrically connected to the second interconnection lines, and
second vias electrically connecting at least one of the second interconnection lines and at least one of the third interconnection lines to each other.

3. The semiconductor device of claim 2, wherein a portion in which the upper ends of the first and second inclined vias are connected to each other is positioned on a level the same or lower than that of uppermost ends of the third interconnection lines.

4. The semiconductor device of claim 1, wherein the connection structure is a signal transmission line electrically connected to the source/drain regions.

5. The semiconductor device of claim 1, wherein the connection structure is a power transmission line electrically connected to the gate structure.

6. The semiconductor device of claim 1, wherein a plurality of the connection structure are provided and each of the plurality of connection structures are positioned on the same level.

7. The semiconductor device of claim 6, wherein the plurality of connection structures are in contact with each other.

8. The semiconductor device of claim 1, wherein
the first inclined via has a first inclination angle with respect to an upper surface of the first line, and
the second inclined via has a second inclination angle with respect to an upper surface of the second line.

9. The semiconductor device of claim 8, wherein the first and second inclination angles have different magnitudes.

10. The semiconductor device of claim 1, wherein the first and second inclined vias have different lengths, on a plane.

11. The semiconductor device of claim 1, wherein the connection structure extends, on a plane, in a direction oblique to each of the first and second directions.

12. The semiconductor device of claim 1, wherein the first vias extend in a direction perpendicular to the first and second directions.

13. The semiconductor device of claim 1, wherein the first and second inclined vias are symmetrical to each other in a direction perpendicular to the upper surface of the substrate.

14. The semiconductor device of claim 1, further comprising:
a barrier layer disposed to be in contact with the second interconnection lines and the first vias,
wherein the barrier layer extends from side and lower surfaces of the second interconnection lines to lower surfaces of the first vias along side surfaces of the first vias.

15. The semiconductor device of claim 1, wherein each of the standard cells further includes first and second contacts respectively connecting the first interconnection lines to the source/drain regions and the gate structure.

16. A semiconductor device comprising:
standard cells on a substrate, the standard cells respectively including an active region, a gate structure disposed to intersect the active region, and source/drain regions disposed on the active region, on both sides of the gate structure;
interconnection lines extending on the substrate in a first direction and a second direction, intersecting the first direction;
vias extending in third direction, perpendicular to an upper surface of the substrate, the vias electrically connecting interconnection lines disposed on different levels along the third direction, among the interconnection lines, to each other; and
a first connection structure connected to respective interconnection lines positioned on the same level, among the interconnection lines, the first connection structure having contact portions having an oblique angle with respect to upper surfaces of the interconnection lines,
wherein the interconnection lines, positioned on the same level, extend in the same direction.

17. The semiconductor device of claim 16, further comprising:
a second connection structure connected to a first interconnection line positioned on a first level and second interconnection line positioned on a second level,
wherein the second connection structure includes contact portions having an oblique angle with respect to upper surfaces of the first interconnection line and the second interconnection line.

18. The semiconductor device of claim 17, wherein the first and second connection structures include a metal material.

19. A semiconductor device comprising:
standard cells on a substrate, the standard cells respectively including an active region, a gate structure disposed to intersect the active region, and source/drain regions disposed on the active region, on both sides of the gate structure;
a contact structure including source/drain contacts and a gate contact respectively connected to the source/drain regions and the gate structure;
interconnection lines electrically connected to each of the source/drain contacts and the gate contact; and
a connection structure connecting different source/drain contacts, among the source/drain contacts, to each other, the connection structure having a plurality of contact portions inclined in a direction perpendicular to an upper surface of the substrate, and a connection portion in contact with a lower surface of at least one of the interconnection lines.

20. The semiconductor device of claim 19, wherein upper ends of the contact portions are connected to each other at the connection portion.
